(19) United States
(12) Patent Application Publication
(10) Pub. No.: US 2005/0140009 A1
(43) Pub. Date: Jun. 30, 2005

(54) Method and apparatus for the production of an electronic component with external contact areas

(76) Inventor: Horst Groeninger, Maxhutte-Haidhof (DE)

Correspondence Address: EDELL, SHAPIRO, FINNAN & LYTLE, LLC, 1901 RESEARCH BOULEVARD, SUITE 400, ROCKVILLE, MD, 20850, US

(21) Appl. No.: 11/012,483

(22) Filed: Dec. 16, 2004

Related U.S. Application Data
(63) Continuation of application No. PCT/DE03/02014, filed on Jun. 16, 2003.

(30) Foreign Application Priority Data
Jun. 17, 2002 (DE) 102 27 045.7

(51) Int. Cl. B05D 1/18; H01L 23/48; H01L 21/44; H01L 23/52; H01L 29/40

(52) U.S. Cl. 257/739; 438/612

(57) ABSTRACT

A method is provided for producing an electronic component with external contact areas which have a layer of metal, the thickness of the layer of the external contact areas decreasing from a central region to a border region. To realize a layer of this type, the electronic component is fluidically processed after its completion, such that the electronic component is heated in a protective gas atmosphere containing formic acid vapor up to at least the flow temperature of the surface of the layer.

### CROSS REFERENCE TO RELATED APPLICATIONS

This application is a continuation of PCT/DE03/02014, filed Jun. 16, 2003, and titled “Method and Apparatus for the Production of an Electronic Component with External Contact Areas,” which claims priority under 35 U.S.C. §119 to German Application No. DE 102 27 045.7, filed on Jun. 17, 2002, and titled “Method and Apparatus for the Production of an Electronic Component with External Contact Areas,” the entire contents of which are hereby incorporated by reference.

### FIELD OF THE INVENTION

On account of the ever larger external areas of electronic components packaged in plastic, external contact areas which are arranged on the underside of the electronic component and serve for connecting the electronic component to higher-level circuit arrangements are becoming increasingly important. Accordingly, the present invention relates to external contact areas of this type taking the place of the contact leads in the form of external flat conductors that have previously been arranged at the border.

### BACKGROUND

To prepare for connecting the external contact areas to a higher-level circuit arrangement or to solder bumps or balls to be additionally provided, these external contact areas are coated with a solderable layer. This layer of metals or metal alloys is electrodeposited on the external contact areas and thereby forms a matte surface with sharp-edged borders. In this connection, electrodepositing is understood as meaning both currentless deposition from a chemical bath and electrolytic deposition by means of current in an electrolyte bath.

However, during functional tests of the conventional electronic component, an electrodeposited layer of this type has unfavorable effects on the transition and contact resistance, and in particular on the service life of the flexible test contacts, especially since they are contaminated with the material of the layer of the external contact areas even after a few test cycles.

### SUMMARY

An aspect of the invention is to improve the properties of electrodeposited layers on external contact areas and to provide an electronic component which makes reliable testing possible along with low contact transition resistances and stable transition resistances of the coated external contact areas.

This aspect is achieved by the subject matter of the independent claims. Advantageous developments of the invention emerge from the dependent claims.

According to an embodiment of the present invention, a method for the production of an electronic component with external contact areas is provided, the external contact areas having a layer of metal or a metal alloy and the thickness of the layer of an external contact decreasing from a central region to a border region. For this purpose, the following method steps are carried out. Firstly, an electronic component is produced with external contact areas having an electrodeposited matte surface, and uneven, sharp-edged layer of metal or metal alloys on the external contact areas. Subsequently, this electrodeposited layer is fluidically processed in that the electronic component is heated in a reducing atmosphere, in particular a protective gas atmosphere containing formic acid, up to at least the flow temperature of the surface of the layer.

This method has the advantage that the method of producing electronic components, including the electrodepositing of layers with matte surfaces, can be retained. The metals and metal alloys that have previously been electrodeposited can also be used unchanged. In addition, the method has the advantage that no mechanical or chemical-mechanical finishing of the external contact areas is required to improve the electrodeposited. The matte and uneven and also sharp-edged layer on the external contact areas are finished in such a way that the matte, and consequently rough, surface is transformed into a shiny and smooth surface. In addition, the method provides an improved layer in that the thickness of the layer of an external contact decreases from a central region to a border region and consequently the sharp-edgedness of the coating of the external contacts is overcome.

It has also been possible to establish that a reducing atmosphere, in particular a protective gas atmosphere containing formic acid, has the effect when the flow temperature of the surface of the layer is reached not only of smoothing the surface of the layer and rounding it off in the border region of the layer but also of freeing the metals or metal alloys of the layer from metal oxides, so that an improved electrical contact resistance and a stable transition resistance can be achieved, for example with respect to test contacts of a test head. Finally, it has been possible to establish that the surface of the layer is hardened at the same time after the fluidic processing has occurred according to the invention, so that an electronic component is obtained with external contact areas which are hardened, smoothed, rounded off in the border regions and free from oxides.

In order to produce a protective gas atmosphere containing formic acid, a protective gas can be passed through a formic acid vapor, HCOOH molecules of the formic acid being entrained with the protective gas. In the case of such an example of how the method is carried out, the concentration of formic acid in the protective gas can be regulated by means of the flow rate of protective gas per unit of time through the formic acid vapor region. In addition, the concentration of formic acid in the protective gas atmosphere containing formic acid can be set by heating formic acid at temperatures between approximately 40° C. and 60° C.

The concentration of the HCOOH molecules can be additionally controlled by a corresponding pressure above the level of the formic acid of between approximately 0.5 and 1 MPa. The pressure in a formic acid vapor generator can be set by the supply of protective gas. The protective gas may take the form of an inert gas which does not enter into any reactions with the formic acid vapor and materials of the electronic component, in particular with the layer to be fluidically processed on the external contacts.

Forming gas, which with its hydrogen component supports the reduction of metal oxides on the surface of the layer, and can also be used as the protective gas.

A further possibility is to use nitrogen as the protective gas. This has the advantage that nitrogen is relatively inexpensive in comparison with other inert gases and can consequently be obtained at low cost.

In a preferred exemplary embodiment of the method, it is provided that the electronic component is heated to a first holding temperature within approximately 20 to 40 seconds and subsequently brought to a second, higher holding temperature in approximately 10 to 30 seconds and, finally, is heated to a highest end temperature, which corresponds at least to the flow temperature of the surface of the layer, in approximately 15 to 30 seconds. After reaching the flow temperature as the highest end temperature of the method, the electronic component can be cooled down at a cooling rate of approximately 5° C. per second to 10° C. per second without microcracks or other defects being ascertainable on the electronic component.

The aforementioned holding temperatures and end temperatures are dependent on the material of the electrodeposited layer on the external contact areas. In the case of a preferred method, the external contact areas are electrodeposited with a solderable layer. For this purpose, a tin/lead alloy which is made up of 80 atomic % tin and 20 atomic % lead is applied to the external contact areas.

The layer may also consist of a tin/lead/silver alloy. In this tin/lead/silver alloy, tin is contained with approximately 50 to 70 atomic %, lead with approximately 30 to 40 atomic % and silver with approximately 1 to 10 atomic %. In the case of a coating of such a composition, the electronic component is firstly heated to a first holding temperature of approximately 100 to 110° C., subsequently to a second holding temperature of approximately 150 to 170° C. and finally to the end temperature of approximately 200 to 220° C. In this case, the first and second holding temperatures lie below the flow temperature of the surface of the respective coating alloy.

The first holding temperature lies above the evaporation point of water, whereby the surface of the electrodeposited layer is dried. The second holding temperature lies a few 10° below the flow temperature of the surface, so that a short heating-up phase is adequate to achieve superficial flowing, and consequently smoothing, of the electrodeposited matte layer. In order to ensure that all the external contacts of an electronic component reliably reach the second holding temperature, the second holding temperature is maintained for approximately 20 to 40 seconds before the electronic component is heated to the end temperature. In this case, the end temperature may lie slightly above the flow limit for the electrodeposited material.

After the fluidic processing of the external contact areas, the electronic component may be tested by pressing flexible measuring contacts onto the coated external contact areas. On account of the smoothing and hardening of the surface of the layer on the external contact areas, the migration of metal alloy constituents such as tin or lead to the flexible contacts of the test head is reduced, so that the service life of the test heads is improved. In addition, a much lower and more uniform transition resistance is provided for the test procedure by the oxide-free surface. This overcomes the disadvantages of matte, uneven and sharp-edged electrodeposited coatings on the external contact areas. In particular, frequent cleaning or premature replacement of the flexible contacts on the test head can be avoided.

The method also offers advantages when contact balls or contact bumps are to be applied to the external contact areas of the electronic component. In this case, the contact balls or contact bumps are pre-adjusted on the external contacts of the components and pre-positioned with flux and subsequently melted onto the coated external contact areas in a protective gas atmosphere containing formic acid. The HCOOH molecules of the formic acid vapor have the effect of reducing the surfaces that are to be fused to one another, formates that occur at the processing temperatures being volatile. Apart from the fusing of oxide-free surfaces, the protective gas atmosphere containing formic acid additionally achieves the effect that the surfaces of the external contact bumps and external contact balls that are produced become surface-hardened and free from oxides.

An apparatus for the production of an electronic component with external contact areas which have a layer of metal or of a metal alloy, the thickness of the layer of each external contact decreasing from the central region to a border region of the external contact areas, has the following devices: a multiple-zone furnace with inlet and outlet ports and with a compressed gas feed and also a formic acid vapor generator with heating means and a protective gas feed, the protective gas feed being connected to the formic acid vapor generator. This apparatus has the advantage that it makes it possible for the multiple-zone furnace to set and regulate separately in different heating zones the first holding temperature, the second holding temperature and the end temperature in the range of the flow temperature of the surface of the layer to be smoothed. In addition, a multiple-zone furnace has the advantage that the method can be carried out in a continuous pass, with for example a cycle sequence of approximately 20 to 30 seconds of dwell time in each of the zones of the furnace.

The formic acid vapor generator acting together with the protective gas feed has the advantage that the mixing between the formic acid vapor and the protective gas can be carried out outside the multipurpose furnace and a feed pressure of the protective gas containing formic acid vapor can be set separately from the volume and the size of the multiple-zone furnace. It is ensured by the compressed gas feed between the multiple-zone furnace and the formic acid vapor generator that an adequate amount of protective gas containing formic acid vapor gets into the multiple-zone furnace and flushes the inlet and outlet ports of the multiple-zone furnace, so that atmospheric oxygen is prevented from getting in through the inlet and outlet ports.

The formic acid vapor generator of the apparatus according to the invention may have a pressure vessel, which is filled in its lower region with formic acid and is surrounded in this region by a heating means, the protective gas feed having a protective gas feed opening above the level of the formic acid. With this embodiment of the formic acid vapor generator, it is ensured that the protective gas feed with its protective gas feed opening does not itself enter the formic acid. Rather, the protective gas, which can flow in through the protective gas feed opening, is directed over the level of the formic acid and becomes saturated with formic acid vapor, so that the protective gas containing formic acid vapor can be fed at a superatmospheric pressure of between approximately 0.5 and 1 MPa to the multiple-zone furnace via the compressed gas feed. For this purpose, the formic acid vapor generator has in its upper region an outlet opening to the compressed gas feed. The compressed gas feed itself is arranged centrally on the multiple-zone furnace, so that the protective gas atmosphere containing formic acid can spread out uniformly in the volume of the furnace both toward the inlet port and toward the outlet port.

Apart from the temperature-regulated heating zones, the multiple-zone furnace may also have in the region of the outlet port a cooling zone, which ensures a cooling rate of 5° per second to 10° per second for the cooling down of the electronic components. In a further embodiment of the apparatus, three heating zones are provided for the different holding temperatures and for the end temperature. This has the advantage that the multiple-zone furnace can be set at relatively short notice to other material compositions of the surface to be smoothed.

The multiple-zone furnace may have a conveyor belt, on which a number of electronic components are arranged for passing through the zones one after the other. A conveyor belt of this type is made up of conveyor belt elements which do not react with the protective gas atmosphere containing formic acid vapor or do not contaminate the electronic components. A conveyor belt of this type may be an endless belt, so that electronic components can be fluidically processed or formed with their external contact areas continually one after the other in the multiple-zone furnace.

The transporting speed of the conveyor belt, the temperature of individual zones of the multiple-zone furnace, the heating of the formic acid vapor generator, the feed pressure in the compressed gas feed and the inert gas throughflow can be controlled, regulated and monitored by means of a central controlling, regulating and monitoring device. By programming the central control device, the forming or fluidic processing, which in an extreme case leads to remelting of the electrodeposited layer, can be controlled fully automatically, so that the method sequences do not require any direct intervention. Furthermore, different sequential programs, which are adapted to the different materials of the electrodeposited layer, may be stored in the control device and suitably called up.

This apparatus can be used to produce an electronic component with external contact areas which have a layer of metal or a metal alloy, the thickness of the layer of an external contact decreasing from a central region to a border region of the external contact area. For this purpose, firstly a flat leadframe is prepared for a number of electronic components with external contact areas. After that, the electronic components on the leadframe are completed, in that semiconductor chips are applied, with the semiconductor chip and its contact areas being connected to the external contact areas of the leadframe, and are packaged on the leadframe in a plastic package molding compound. Subsequently, a layer is electrodeposited on the leadframe for a number of components in the leadframe assembly simultaneously, with the external contact areas being coated (with metal or a metal alloy). Finally, the layer on the external contact areas of the electronic components in the leadframe assembly is fluidically processed, with the electronic components being heated in a protective gas atmosphere containing formic acid vapor up to at least the flow temperature of the surface of the layer. By punching out the components with electrodeposited and fluidically processed external contact areas from the leadframe, the components of the leadframe are singularized.

This produces an electronic component which not only has a surface reduced with respect to metal oxides, on account of the action of the formic acid, but also has a shiny and smooth surface, is completely oxide-free and has a low contact resistance, on account of the thermal treatment. In addition, the fluidic treatment under formic acid vapor has the effect that the surface is hardened in comparison with the electrodeposited surface, so that the migration of lead or tin during the testing of the electronic components is lessened. This simultaneously reduces the risk of contamination for the test heads with which the functional capability of the electronic components is checked.

The metal alloys of the layers on the external contacts of the electronic component according to the invention may be alloys of tin/lead or tin/lead/silver or bismuth/silver/copper or bismuth/nickel/copper. These alloys have the common property that they are solderable. They make it possible for the external contact areas to be connected directly to corresponding contact areas of a higher-level circuit system. The specific composition of the alloys has already been stated above for tin, lead and silver, while the metal alloy bismuth/silver/copper preferably has approximately 50 to 80 atomic % bismuth, 5 to 40 atomic % silver and 0.5 to 15 atomic % copper. This alloy has the advantage that it does not have the highly toxic heavy metals tin and lead. An alloy which is based on bismuth/nickel/copper preferably has approximately 50 to 85 atomic % bismuth, 15 to 45 atomic % copper and 0.5 to 5 atomic % nickel.

While the first holding temperature for drying the coating lies at temperatures between 100 and 110° for all the alloy layers, the second holding temperature is arranged a few 10° below the flow temperature of the surface of the respective layer and consequently varies between the individual alloys used. The same applies to the highest end temperature, which is intended to reach at least the flow temperature of the respective alloy. This is also individually dependent on the metal alloys of the layer that are used. By contrast, however, the generation of the protective gas atmosphere containing formic acid vapor for the electronic component according to the invention can correspond to the method described above, the pressure in the compressed gas feed being of the same order of magnitude, lying between approximately 0.5 and 1 MPa.

As in the method described above, the dwell times at the different holding temperatures lie between 10 and 40 seconds, the heating-up time between the first holding temperature and the second holding temperature being in turn dependent on the flow temperature of the respective alloy of the layer. The cooling rate after reaching the flow temperature may lie in the range specified above of approximately between 5° C. per second and 10° C. per second and is merely dependent on the thermal shock sensitivity of the electronic component, and primarily has no dependence on the composition of the metal alloy for the layer applied to the external contact areas.

To sum up, it can be stated that, by remelting the electroplating of external contact areas under an atmosphere preferably comprising nitrogen and formic acid vapors, a smooth, hardened and virtually oxide-free surface with more favorable properties with respect to contact soiling, migration and transition resistance is obtained. Since no flux is used in the case of this method according to the invention, no subsequent cleaning of the components is required either. The formates produced during the fluidic processing in the protective gas atmosphere containing formic acid vapor are removed by the suction extraction system of the furnace at the inlet and outlet ports.

A remelting of electrodeposited layers on the external contact areas can be carried out for all the electronic components in the protective gas atmosphere containing formic acid vapor and has proven successful for P-VQFN components. In order to obtain an appropriately high concentration of the formic acid vapors in the protective gas atmosphere, the pressure vessel of the formic acid vapor generator is heated up to a temperature of approximately between 40 and 60° C.

Fluidic finishing of electrodeposited layers should take place immediately after the electrodepositing, or the component should be temporarily stored in an inert gas atmosphere containing nitrogen, especially since the production process does not proceed optimally and uniformly in the formic acid vapor in the case of thicker oxides, which are produced in the event of temporary storage in air. Apart from using the method according to the invention for the fluidic processing of coated external contact areas, it is also possible to fuse on contact balls of BGA components (ball grid array components) after attaching the contact balls to the corresponding external contact areas. In this case, a better-comparable test result is obtained in the functional test of the electronic components as a result of the oxide-free balls.

The above and still further aspects, features, and advantages of the present invention will become apparent upon consideration of the following definitions, descriptions and descriptive figures of specific embodiments thereof wherein like reference numerals in the various figures are utilized to designate like components. While these descriptions go into specific details of the invention, it should be understood that variations may and do exist and would be apparent to those skilled in the art based on the descriptions herein.

### BRIEF DESCRIPTION OF THE DRAWINGS

The invention is now explained in more detail on the basis of exemplary embodiments with reference to the accompanying figures.

FIG. 1 shows a basic diagram of an apparatus for carrying out the method according to the invention;

FIG. 2 schematically shows an enlarged cross section through an external contact with an electrodeposited layer;

FIG. 3 schematically shows an enlarged cross section through an external contact with an electrodeposited layer after fluidic processing of the layer;

FIG. 4 shows a basic temperature-time diagram of a fluidic processing of an electronic component with coated external contact areas;

FIG. 5 schematically shows a side view of a P-VQFN component with fluidically processed layers on external contact areas; and

FIG. 6 shows a schematic view from below of the P-VQFN component of FIG. 5.

### DETAILED DESCRIPTION

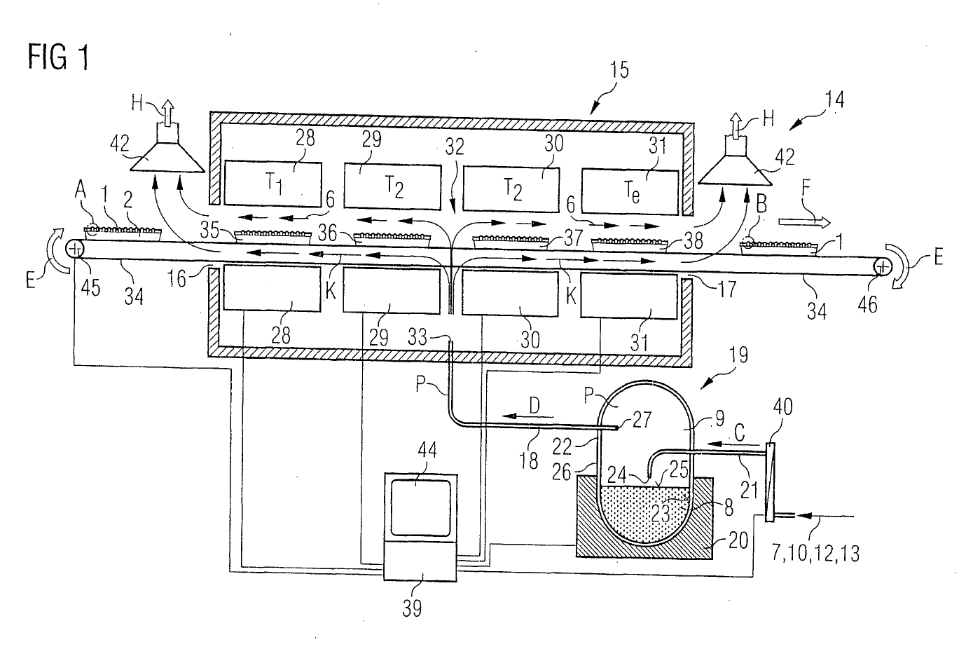

FIG. 1 shows a basic diagram of an apparatus 14 for carrying out the method according to an embodiment of the present invention. The reference numerals 1, 35, 36, 37 and 38 identify electronic components which are being transported on a conveyor belt 34 through a multiple-zone furnace 15 step by step through the heating zones 28, 29, 30 and 31 of the multiple-zone furnace 15. The reference numeral 6 identifies a protective gas atmosphere containing formic acid vapor, which flows through the multiple-zone furnace 15 in the direction of the arrows K and fills the entire inner volume of the furnace 32. The reference numeral 7 identifies a protective gas, which is forced under a pressure P of approximately 0.5 to 1 MPa via a flowmeter 40 and a protective gas feed 21 in the direction of the arrow C into a pressure vessel 22 of the formic acid vapor generator 19. Hereinafter, although the term “approximate” may be omitted, the values of bounds of the various ranges disclosed herein should be considered approximate values.

The reference numeral 8 identifies formic acid, which is arranged in the formic acid vapor generator 19 in the lower region 23 of the pressure vessel 22. The reference numeral 9 identifies formic acid vapor, which is formed above the liquid level 25 of the formic acid 8 on account of the formic acid 8 being heated up by a heater 20 surrounding the lower region 23 of the pressure vessel 22. This heater 20 keeps the temperature of the formic acid 8 at 40° C. to 60° C. The protective gas 7 flowing out from the protective gas feed opening 24 has the effect that the formic acid vapor 9 is introduced approximately centrally into the multiple-zone furnace 15 in the direction of the arrow D via a compressed gas feed 18.

In order to achieve intensive mixing of the formic acid vapor with the protective gas, the protective gas feed opening 24 is arranged above the level of the formic acid 25. The outlet opening 27 for the protective gas 7 containing formic acid vapor is arranged in the upper region 26 of the vapor generator 19. Inert gases 10, forming gases 12 or nitrogen 13 can be directed as protective gas 7 via the flowmeter 40 into the formic acid vapor generator 19 via the protective gas feed 21 and the protective gas feed opening 24. While inert gas and nitrogen do not react in any way with the formic acid and with the electronic components and the layer on the external contact areas of the electronic components, forming gas has the effect, as a result of its hydrogen content, of supporting the reduction of weakly oxidized surfaces of the electrodeposited layers on the external contact areas of the electronic components 35, 36, 37 and 38, which are located in the protective gas atmosphere containing formic acid vapor of the multiple-zone furnace.

During the operation of the furnace 15, the inner volume of the furnace 32 is completely filled with protective gas atmosphere 6 containing formic acid vapor and, on account of a superatmospheric pressure, the protective gas atmosphere containing formic acid vapor leaves both at the inlet port 16 and at the outlet port 17 of the multi-zone furnace 15 and is collected by the extractor hoods 42 and fed in the direction of the arrow H to a waste-gas cleaning system. For the protective gas atmosphere 6 containing formic acid vapor to be introduced into the multi-zone furnace 15 in a centered manner, an opening 33 of the pressure feed 18 is arranged centrally in the multi-zone furnace 15 between the central heating zones 29 and 30.

The reference numeral 39 identifies a controlling, regulating and monitoring device, which has a monitor 44 for monitoring the functional capability of the apparatus. The controlling, regulating and monitoring device 39 is in connection with the flowmeter 40, in order to regulate the throughflow of the protective gas 7. Further data lines of the controlling, regulating and monitoring device connect the latter to the heating means 20 of the formic acid vapor generator 19 for regulating and maintaining the temperature of the formic acid 8 and further data lines connect the controlling, regulating and monitoring device 39 to the heating zones 28, 29, 30 and 31 of the multiple-zone furnace 15.

The drive roller 45 of the conveyor belt 34 is controlled by means of a further data line, which is in operative connection with the conveyor belt 34, in order to ensure constant dwell times of the electronic components 35, 36, 37 and 38 in the zones 28, 29, 30 and 31 of the multiple-zone furnace 15. For this purpose, the drive roller 45 is rotated in the direction of the arrow E, so that the electronic components can be transported in the direction of the arrow F. The deflecting roller 46 on the outlet port side returns the endless conveyor belt 34 to the drive roller 45 with the same direction of rotation E as the drive roller 45.

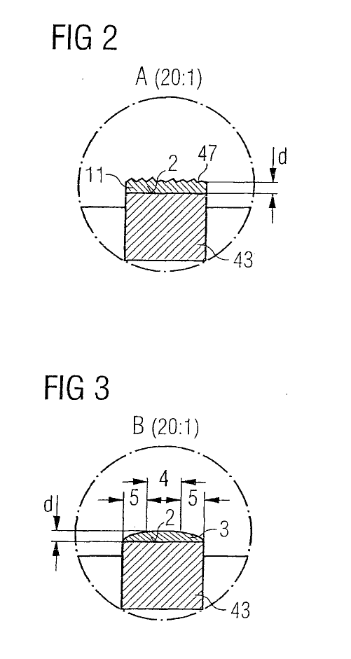

FIG. 2 schematically shows an enlarged detail A of FIG. 1 with an enlarged cross section through an external contact 43 of an electrodeposited layer 11. The components 1 have external contacts 43 of this type with electrodeposited layers of solderable material when they are transported via the inlet port 16 on the conveyor belt 34 by a first contact step into the position of the heating zone 28. The electrodeposited layer 11, shown in FIG. 2, on the external contact area 2 of the external contact 43 exhibits a matt surface, which is correspondingly rough and uneven and has relatively sharp edges 47, which are produced during the electrodepositing.

A component with external contact areas of this type can considerably damage a test head, which is intended to check the function of the electronic components, because an increased migration of constituents of the solderable alloy, such as tin/lead/silver or bismuth/silver/copper or bismuth/nickel/copper occurs. In the case of a tin/lead/silver contact, the layer 11 has 50 to 70 atomic % tin, 30 to 40 atomic % lead and 1 to 10 atomic % silver. In the case of a bismuth/silver/copper layer, the metal alloy has 50 to 80 atomic % bismuth, 5 to 40 atomic % silver and 0.5 to 15 atomic % copper. In the case of a bismuth/nickel/copper alloy, the layer has 50 to 85 atomic % bismuth, 15 to 45 atomic % copper and 0.5 to 5 atomic % nickel.

A layer 11 of this type, as shown in FIG. 2, is brought with the component 1 via the inlet port 16, as shown in FIG. 1, on the conveyor belt 34 into the first heating zone 28, in which the electronic component is heated up to a first holding temperature T₁ of from 100 to 110° C., in order to free the surfaces from moisture. After this drying, which is ended after a dwell time of Δt, the conveyor belt 34 will bring the electronic component step by step into the second heating station 29, which is heated up to a second holding temperature T₂.

The holding temperature T₂ lies a few 10° C. below the flow temperature of the surface of the electrodeposited layer 11. After a heating-up phase, which also takes approximately the time interval Δt, the electronic component is moved into the third heating zone 30, which likewise lies at the holding temperature T₂, so that the temperature in the entire electronic component can stabilize. Only after the electronic component is brought into the fourth position, which lies at the highest temperature of an end temperature Tₑ, which corresponds at least to the flow temperature of the electrodeposited layer 11 and, after an equal dwell time in this fourth heating zone, the component is cooled down to room temperature by moving it out from the outlet port 17.

FIG. 3 schematically shows an enlarged detail B of FIG. 1 with an enlarged cross section through an external contact 43 of an electrodeposited layer after a fluidic processing of the layer. The fluidically processed layer 3 on the external contact 43 has a smooth, shiny surface, on which all the unevennesses have been leveled out, and has a greater thickness d in a central region 4 than in the border regions 5, in which it is rounded off and falls away toward the edges. Apart from the purely geometrical change of the fluidically processed layer 3, this layer 3 also has a higher surface hardness than the layer 11, which is shown in FIG. 2. In addition, the fluidically processed layer 3 has been reduced by the HCOOH molecules of the formic acid vapor, so that a pure metal surface is obtained on the external contacts 43 of the electronic component. The reduction of the surface of the electrodeposited layer 11 can be supported by the protective gas, in that the forming gas 12, which apart from nitrogen 13 also contains reducing hydrogen molecules, is introduced in place of an inert gas 10.

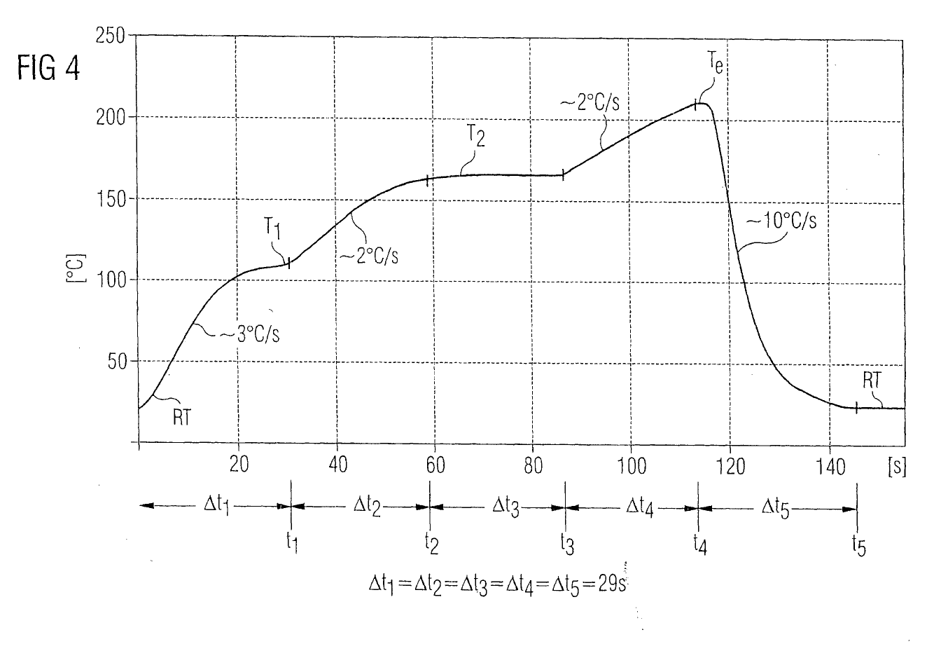

FIG. 4 shows a basic temperature-time diagram of a fluidic processing of an electronic component with electrodeposited external contact areas. FIG. 4 shows the time t in seconds on the x axis and the temperature T in ° C. on the y axis.

The room temperature is identified by RT; two holding temperatures T₁ at 110° and T₂ at 170° can also be seen as stages in the temperature-time diagram. After the second holding temperature T₂, the electronic component is heated up by approximately 2° C. per second to the highest end temperature Tₑ, which corresponds at least to the flow temperature of the metal alloy of the electrodeposited layer. Immediately after reaching this highest temperature Tₑ, the electronic component can either be actively cooled at up to 10° C./s or be moved out of a multiple-zone furnace and cooled down to room temperature RT.

The four dwell times Δt, to Δt₄ shown here are equally long and correspond to the four dwell times which are possible in the apparatus 14, as FIG. 1 shows, with the four heating zones 28, 29, 30 and 31. The dwell time Δt in this exemplary embodiment is 29 seconds, so that the electronic component can be brought into the next heating zone step by step every 29 seconds. During the first dwell time Δt₁ in the first heating zone of the multiple-zone furnace of FIG. 1, the holding temperature T₁, which lies above the evaporation point of water under normal pressure, is reached at the electronic component at an average temperature increase of 3° C./s. After that, in the second dwell time Δt₂, the component is heated up to the second holding temperature T₂ at a temperature increase of 2° C./s.

During a third dwell time Δt₃, the electronic component is kept at the second holding temperature T₂ in the third heating zone and, during the fourth dwell time Δt₄, is heated to the highest end temperature Tₑ, which corresponds at least to the flow temperature of the surface of the electrodeposited layer, in the fourth heating zone of the multiple-zone furnace at a temperature increase of 2° C./s. For this example of how the method according to the invention is carried out, the diagram shows the cooling down of the electronic components to room temperature RT after moving the electronic component out of the multiple-zone furnace 15, as it is shown in FIG. 1. When this happens, the morphology of the electrodeposited layer on the external contact areas has changed, as a comparison of FIGS. 2 and 3 shows.

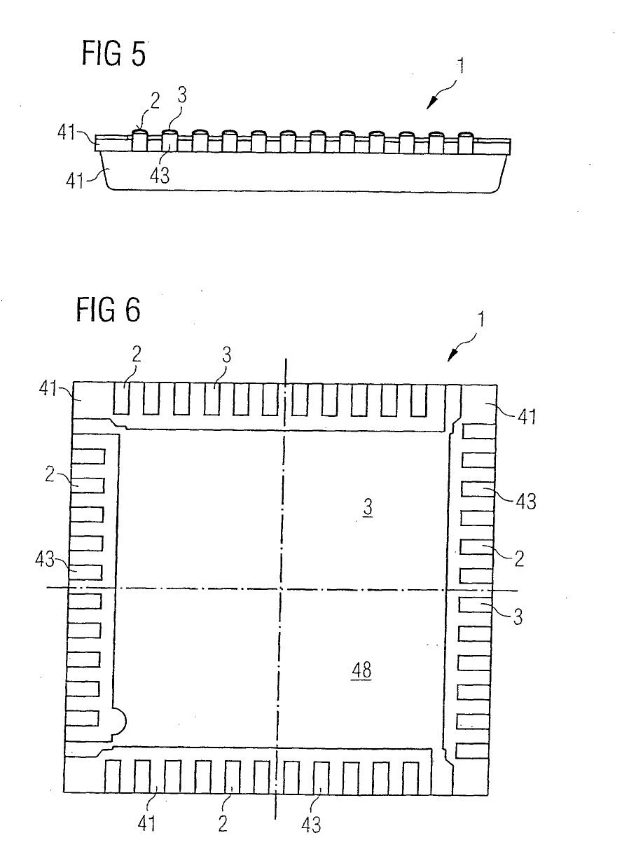

FIG. 5 schematically shows a side view of a P-VQFN component with fluidically processed layers 3 on external contact areas 2. In this case, the external contacts 43 are embedded in a plastic package molding compound 41 and are kept in position by the latter. Each of the twelve external contacts 43 in this side view has a smooth, shiny, solderable layer 3, which has a greater hardness in comparison with the originally electrodeposited layer in this region, and consequently lessens a migration of material from these solder layers during the testing of the electronic component 1.

FIG. 6 schematically shows a view from below of the P-VQFN component of FIG. 5, a large-area external contact 48 covering the inner center of the underside of the electronic component. The fluidically processed layer 3 lies on this large-area external contact and covers the entire surface area of the large-area external contact 48, which serves as a chip island and carries the semiconductor chip, which is not visible from the view from below shown here. Altogether, 48 contact areas 2 are arranged in the border region of the plastic package molding compound 41, four of which are electrically connected to the large-area external contact 48 of the chip island. Both the large-area external contact 48 and the external contacts 43 in the border region of the electronic component are embedded in the plastic package molding compound 41 and are on the one hand exposed from the view from below shown here and additionally accessible at the side regions shown in FIG. 5.

While the invention has been described in detail and with reference to specific embodiments thereof, it will be apparent to one skilled in the art that various changes and modifications can be made therein without departing from the spirit and scope thereof. Accordingly, it is intended that the present invention covers the modifications and variations of this invention provided they come within the scope of the appended claims and their equivalents.

1. A method for producing an electronic component with external contact areas including a layer of metal or of a metal alloy, wherein the thickness of the layer of the external contact areas decreases from a central region to a border region, the method comprising:
producing the electronic component with the external contact areas, including an electrodeposited, matte, uneven and sharp-edged layer of metal or metal alloys on the external contact areas; and
fluidically processing the layer on the external contacts of the electronic component by heating the electronic component in a reducing atmosphere up to a flow temperature of a surface of the layer.

2. The method as claimed in claim 1, wherein a formic acid vapor comprising protective gas atmosphere is generated as a reducing atmosphere.

3. The method as claimed in claim 2, wherein a formic acid vapor for the formic acid vapor comprising protective gas atmosphere is generated by heating formic acid at a temperature of between approximately 40° C. and 60° C. and at a pressure of between approximately 0.5 and 1 MPa.

4. The method as claimed in claim 1, wherein the electronic component is heated to a first holding temperature (T₁) of approximately 100 to 110° C. in approximately 20 to 40 seconds.

5. The method as claimed in claim 4, wherein the electronic component is heated to a second higher holding temperature (T₂) of approximately 150 to 170° C. in approximately 10 to 30 seconds.

6. The method as claimed in claim 5, wherein the electronic component is heated to an end temperature (Tₑ) of approximately 200 to 220° C. in approximately 15 to 30 seconds.

7. The method as claimed in claim 5, wherein the electronic component is kept at the second holding temperature (T₂) for approximately 20 to 40 seconds.

8. The method as claimed in claim 1, wherein almost immediately after reaching an end temperature (Tₑ), the electronic component is cooled down to room temperature (RT) at a rate of approximately 5° C./s to 10° C./s.

9. An apparatus for the production of an electronic component with external contact areas including a layer of metal or of a metal alloy, the apparatus comprising:
a multiple-zone furnace with an inlet port and an outlet port;
a compressed gas feed; and
a formic acid vapor generator including heating means and a protective gas feed, the compressed gas feed being coupled to the formic acid vapor generator, and the compressed gas feed being arranged centrally on the multiple-zone furnace.

10. The apparatus as claimed in claim 9, wherein the formic acid vapor generator includes a pressure vessel that is filled in its lower region with formic acid and is surrounded by the heating means, protective gas feed including a protective gas feed opening above the level of the formic acid.

11. The apparatus as claimed in claim 9, wherein the multiple-zone furnace includes at least three heating zones after the inlet port and at least one cooling zone in the region of the outlet port, wherein the inlet port and the outlet port are supplied with protective gas comprising formic acid vapor via the multi-zone furnace and the centrally arranged opening of the pressure feed.

12. The apparatus as claimed in claim 9, wherein the multiple-zone furnace includes a conveyor belt on which a number of electronic components are arranged for passing the number of electronic components through the multiple-zone furnace one after the other.

13. An electronic component, comprising:
a plurality of external contact areas including an electrodeposited and fluidically processed layer, wherein the thickness of the layer of the external contact areas decreases from a central region to a border region of the external contact area, the layer comprising a metal alloy including at least one of: tin/lead, tin/lead/silver, bismuth/silver/copper, and bismuth/nickel/copper.

14. The electronic component as claimed in claim 13, wherein the electrodeposited and fluidically processed layer comprises approximately 50 to 70 atomic % tin, approximately 30 to 40 atomic % lead and approximately 1 to 10 atomic % silver.

15. The electronic component as claimed in claim 13, wherein the electrodeposited and fluidically processed layer comprises approximately 50 to 80 atomic % bismuth, approximately 5 to 40 atomic % silver, and approximately 0.5 to 15 atomic % copper.

16. The electronic component as claimed in claim 13, wherein the electrodeposited and fluidically processed layer comprises approximately 50 to 85 atomic % bismuth, approximately 15 to 45 atomic % copper, and approximately 0.5 to 5 atomic % nickel.

17. The electronic component as claimed in claim 13, wherein the electrodeposited and fluidically processed layer comprises approximately 80 atomic % tin.
